(19) United States
(12) Patent Application Publication
(10) Pub. No.: US 2021/0082876 A1
(43) Pub. Date: Mar. 18, 2021

(54) ELECTRIC DEVICE WITH TWO OR MORE CHIP COMPONENTS

(71) Applicant: RF360 EUROPE GMBH, Munchen (DE)

(72) Inventors: Shook Fong HO, Republic of Singapore (SG); See Jin HOO, Republic of Singapore (SG)

(21) Appl. No.: 16/772,301

(22) PCT Filed: Nov. 19, 2018
(86) PCT No.: PCT/EP2018/081804

§ 371 Date: Jun. 12, 2020

(30) Foreign Application Priority Data
Dec. 12, 2017 (DE) 10 2017 129 611.5

(51) Int. Cl. H01L 25/065; H01L 23/13; H01L 23/00; H01L 23/31

(52) U.S. Cl. CPC H01L 25/0657; H01L 23/13; H01L 24/05; H01L 2924/1421; H01L 23/3121; H01L 2924/1461; H01L 24/13

(57) ABSTRACT

An electric device comprises a substrate (SU) as a carrier and at least two chip components mounted thereto. In the top surface of the substrate a recess (RC) is formed. One or more chip component (BC) is mounted to the bottom surface of the recess referred to as buried chip component. One or more top chip component (TC) is mounted to the top surface of the substrate to cover at least to some extend the recess and the buried chip component. Device pads (PD) are arranged on the bottom surface of the substrate. Each of them is electrically interconnected with one or both of the chip components.

Electronic devices and apparatuses comprising same are subjected to continuous miniaturization trends. Moreover; smaller electronic devices have smaller dimensions, less power consumption and similar or better performance in view of bigger devices.

3-D integration is a further way to shrink the footprint of electronic devices and to save area on the according PCB the device is mounted to. In known solutions two or more chips of electronic devices may be stacked one above the other. The stacked chips may be in direct mechanical contact or require spacers and/or intermediate isolating layers. Making and handling of such stacked devices requires enhanced effort and can possibly cause problems and may have a reduced mechanical stability and electric interconnection that are less stable and hence, less reliable. Further, the height of the total arrangement may be too big.

It is an object of the present invention to provide an electric device that allows to save space thereby avoiding the problem of stacking.

These and other objects are met by an electric device according to claim one. More detailed and more sophisticated features are given by dependent sub-claims.

An electric device is provided comprising a substrate as a carrier and at least two chip components mounted thereto. In the top surface of the substrate a recess is formed. A first chip component is mounted to the bottom surface of the recess referred to as buried chip component. A top chip component is mounted to the top surface of the substrate to cover at least to some extend the recess and the buried chip component. Device pads are arranged on the bottom surface of the substrate. Each of them is electrically interconnected with one or both of the chip components.

Such a device provides 3-D integration by arranging two chip components at least to some extend one above the other. In a preferred embodiment the required chip area of the device complies with the area of the larger chip component that may be the top chip component. The bottom chip component is mounted to the bottom surface of the recess. The top component is mounted to the top surface of the substrate. This means that no direct contact between the two chip components is required and can hence be avoided.

The device requires a reduced surface area according to the overlap of the buried chip component and top chip component. Mechanical stability of the device is only negligibly reduced by the recess. However, as the recess has only a top opening the remaining substrate portions guarantee enough stability. Moreover, the top chip component provides additional mechanical stability by bridges the recess. Advantageously this “bridge” is anchored to the top surface of the substrate on opposing sides of the recess.

The substrate may be chosen from a PCB, a multi-layer wiring board made of ceramic or laminate or something similar. The substrate comprises at least one wiring layer that is electrically interconnected to the chip components and the device pads. The wiring layer(s) is/are arranged within the substrate. Different wiring layers need to be separated by an isolating intermediate layer that is a layer of the substrate material. Two or more wiring layers may be interconnected by vias. Further, the wiring layer(s) need to be connected to the device pads to provide terminals for electrically contacting the device to an external circuitry.

Electrical interconnects of the top chip component to the top contact pads and of the buried chip component to the bottom contact pads and hence to connect it with the wiring layer are made by SMT interconnect, solder bumps, stud bumps, copper pillars, electrically conductive adhesive, etc.

The chip components may comprise passive or active electric devices. One of the chip components may be an IC. However it is advantageous if at least the buried chip component is a MEMS or SAW/BAW component because of the improved protection thereof within the recess that is covered by the top chip component. Even if not a MEMS or SAW/BAW device the chip component that is more sensitive to mechanical stress may be mounted as the buried chip component to be better protected.

In addition or as an alternative embodiment the top chip component may be a MEMS or SAW/BAW component that is advantageously mounted by flip chip-technology. The recess below the top chip component provides a cavity for the MEMS structures to allow undisturbed operation thereof including movement of structures or vibrations.

The chip components may independently comprise an acoustic wave component like a SAW or a BAW device, and may be at least part of an RF filter device as used in wireless applications for example.

The two chip components may be of the same type but may be different too.

The device is not restricted to two chip components only.

Either of top and buried chip components may comprise at least a second chip component arranged and mounted the same way adjacent to the respective first chip component. When multiplying the number of at least one of the chip components the top chip component does not longer need to have the greater chip area. Only one dimension of the top chip component needs to extend the diameter of the recess. Two or more of these top chip components may commonly cover the recess. The recess may be fully closed by the at least one top chip component. If at least the longer dimension of the top chip component is oriented perpendicular to the longest dimension of the recess no limitations in size or size relation are present any more. Two or more buried chip components may be arranged adjacently in the recess and the recess may be closed from the top by one single top chip component only having an area greater than the cross sectional area of the recess.

According to an embodiment a protection layer is applied to cover the upper surface of the one or more top chip components totally as well as at least a margin area of the top surface of the substrate surrounding the top chip components. Thereby the protection layer seals to the top surface in the margin. Thereby the recess and the buried chip components are arranged in a sealed cavity enclosed between protection layer and the substrate. The protection layer may have the only purpose of mechanically keeping the cavity free from further packaging material to be deposited on top of the protection layer.

In one embodiment, a mold is applied on top of the protection layer to provide high mechanical and hermetical protection of the device. Injection molding may be used or any other suitable application method like dosing, casting, rolling on of a film or laminating.

According to an embodiment the protection layer comprises a laminated foil chosen from a plastic film or from a plastic film coated with an inorganic material like a ceramic layer or a metal layer. It is advantageous if the plastic film is applied to the surface in a B-stage where it still has thermoplastic properties. Finally, the plastic may be hardened in a thermal step.

The at least one top chip component is mounted to top contact pads arranged on the top surface near and along the edges of the recess. The at least one buried chip component is mounted to bottom contact pads arranged on the bottom surface of the recess. Electrical interconnects of the top chip component to the top contact pads and of the buried chip component to the bottom contact pads are made by SMT interconnect, solder bumps, stud bumps, copper pillars, electrically conductive adhesive, etc

Preferably, the height of the recess plus the height of the interconnects are chosen to leave a gap between the top surface of the buried chip component and the bottom surface of the top chip component above. This gap guarantees free operation of the buried and/or top chip component that may be a MEMS or a component operating with acoustic waves.

In the following the invention is explained in more detail by reference to specified embodiments and the accompanying figures. The figures are schematic only and not drawn to scale. Hence, some details may be depicted in enlarged form for better understanding.

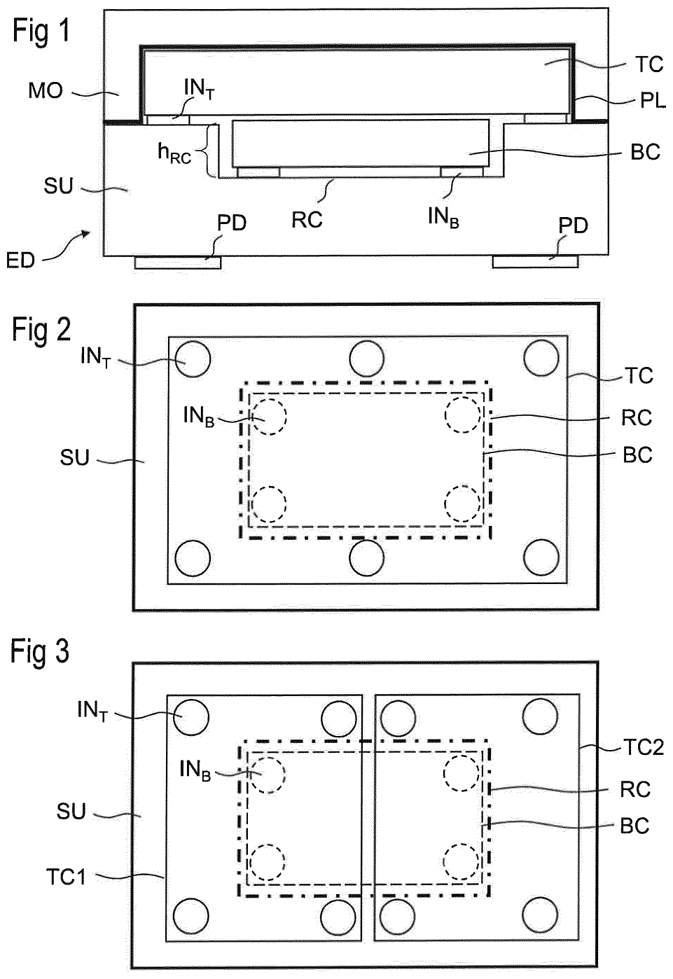

FIG. 1 shows a device according to a first embodiment of the invention in a cross-sectional view.

FIG. 2 shows the device of FIG. 1 device in a top view.

FIG. 3 shows a second embodiment in a top view.

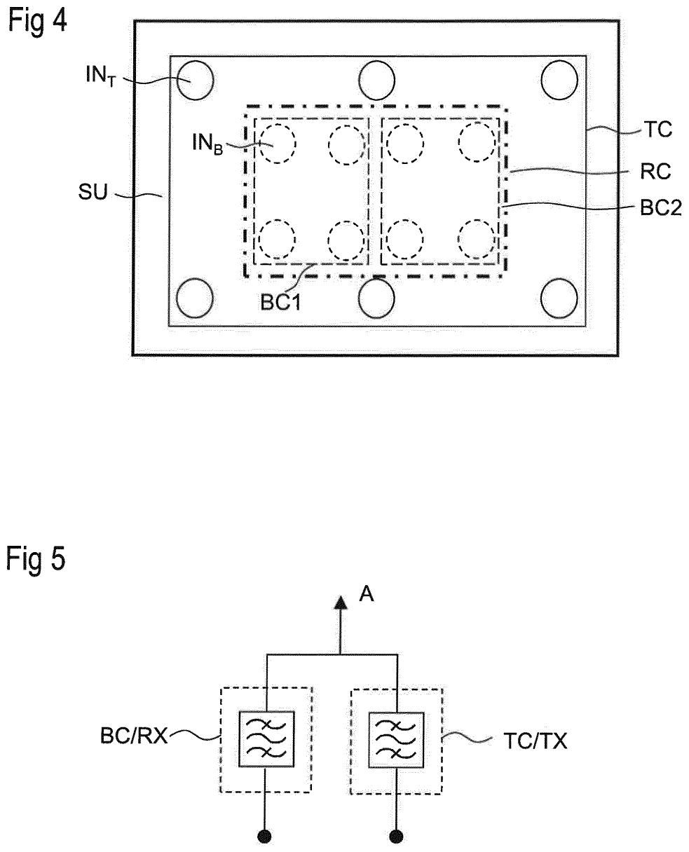

FIG. 4 shows a third embodiment in a top view.

FIG. 5 shows a block diagram of device realized as a duplexer.

A cross-sectional view of a device according to a first embodiment of the invention is shown in a FIG. 1. In the top surface of a substrate SU formed from a multi-layer carrier material such as a laminate a recess RC is formed. On the plane bottom surface of the recess bottom contact pads are formed. On the top surface of the substrate SU near the edge of the recess RC top contact pads are formed. All contact pads are electrically connected to and/or interconnected by a wiring layer within the bulk body of the substrate SU (not shown for clarity reasons). On the exterior bottom surface of the substrate are pads for contacting the device to an external circuitry. Pads PD, wiring layer and contact pads are vertically interconnected by vias (not shown in the figure).

A bottom chip component BC that is for example a SAW component such as a filter is mounted to the bottom contact pads by first interconnects IN_{B} usually via a bump connection. The first interconnects IN_{B} may be stud bumps or solder bumps. A top chip component TC that is for example a

BAW filter is mounted to the top contact pads by second interconnects IN_{T} which can be a solder bump connection IN_{T}. The height h_{RC} of the recess RC and the height the second interconnects IN_{T} add to a value that is chosen to be larger than the height of the bottom chip component BC plus the first interconnects IN_{B}. Thus, a gap remains between bottom chip component BC and the top chip component TC.

A protection layer PL is laminated to the top surface of the top chip component TC and the adjacent free surface of the substrate SU where it makes a seal along the perimeter of the top chip component TC. The protection layer PL is a plastic foil applied in its B-stage and hardened after lamination.

Over the entire top surface of the protection layer PL a mold MO is applied. The mold provides a plane top surface and further mechanically and/or hermetically protects the device.

FIG. 2 is a top view onto the device of FIG. 1. The substrate SU and the recess RC therein is depicted by a stronger line. The top chip component TC totally covers the recess plus a margin of the substrate around the recess RC. First interconnects IN_{T} are located in the margin area to interconnect top chip component TC to the top contact pads. The bottom chip component BC fits into the recess RC with at least a small tolerance and contacts to the bottom contact pads via first interconnects IN_{B}. Laminate (protection layer PL) and mold MO comply in area with the substrate.

FIG. 3 is a top view onto a device according to a second embodiment. Here, one bottom chip component BC is arranged and mounted within the recess RC. Two top chip components TC1, TC2 are arranged and mounted adjacent to each other to commonly cover the whole area of the recess plus a margin of the top surface of the substrate SU. Each of the two top chip components TC1, TC2 bridges the recess RC. The two top chip components TC1,TC2 may have the same or a different size.

FIG. 4 is a top view onto a device according to a third embodiment. Here, two bottom chip components BC1, BC2 are arranged and mounted adjacent to each other within the recess RC. The two bottom chip components BC1,BC2 may have the same or a different size but are smaller than in the first embodiment. The top chip component TC can have the same size like in the first embodiment shown in FIGS. 1 and 2 to cover the whole area of the recess plus a margin of the top surface of the substrate SU.

It is advantageous to couple bottom and top chip component BC, TC to desired device. In the mentioned example this may be a filter device comprising a first filter embodied by the bottom chip component BC that is a SAW component and a second filter embodied by the top chip component TC that is a BAW component. Both filters have distinct pass bands assigned to a TX band for the BAW filter and assigned to an RX band for the BAW filter (top chip component). Together the device with the two chip components can form a duplexer.

FIG. 5 shows a block diagram of a duplexer that is realized from a bottom chip component BC and a top chip component TC in a device according to the invention. The top chip component may be a band pass filter made in BAW technology functioning as a TX filter of the duplexer. The bottom chip component BC may be a band pass filter made in SAW technology functioning as an RX filter of the duplexer. However the assignment of bottom or top chip component to a filter technology or to TX and RX does can be done arbitrarily and independently according to specific requirements. Both filters are connected to an antenna terminal A and circuited to enable a duplexer function. This provides extra benefits when Tx and Rx are using different wafer material, and the characteristics of different materials gives advantages of the filter performance.

However, any possible combination of different chip components can be used for the proposed device. One chip component for example may be an active component like a LNA or a power amplifier and the other chip component may be a SAW filter. Then the proposed device can deliver a processed and amplified filtered signal.

It is also possible to have a MEMS switch as bottom chip component with a Nin1 SAW filter as top chip, which allows to select different bands of the Nin1 SAW filter with the control of the MEMS.

### LIST OF USED REFERENCE SYMBOLS

BC buried chip component (active or passive components, IC like ASIC, MEMS, LNA, acoustic wave component, SAW or BAW component, filter)
ED electric device, in a package
h_{RC} height of recess RC
IN_{B} first interconnects to BC: solder bump, stud bump, pillar bump, SMT, conductive adhesive
IN_{T} second interconnects to TC
MO mold, encapsulation material
PD device pad to external circuit
PL protection layer (lamination foil, metal, glass, compound layer)
RC recess
SU substrate (PCB, ceramic, HTCC, LTCC, FR4/PPG, laminate, . . . )
TC top chip component (active or passive component, IC like ASIC, MEMS, LNA, acoustic wave component, SAW or BAW component, filter)

1. An electric device, comprising:
a substrate (SU)
a recess (RC) in the top surface of the substrate
a buried chip component (BC) mounted to the bottom surface of the recess (RC)
a top chip component (TC), mounted to the top surface of the substrate to cover at least to some extend the recess (RC) and the buried chip component (BC)
device pads (PD) arranged on the bottom surface of the substrate and being electrically interconnected with one or both of the chip components (BC,TC).

2. The electric device of claim 1,
wherein the substrate (SU) is a PCB, a multi-layer wiring board made of ceramic or laminate, comprising a wiring layer electrically interconnected to the chip components (BC,TC) and the device pads (PD).

3. The electric device of claim 1,
comprising at least a second top chip component (TC2) arranged adjacent to the first top chip component (TC1) on the top surface of the substrate (SU), and/or at least a second buried chip component (BC2) arranged adjacent to the first buried chip component on the bottom surface of the recess.

4. The electric device of claim 1,
wherein a protection layer (PL) is applied to cover the upper surface of the one or more top chip components (TC) and the surrounding top surface of the substrate (SU), thereby sealing to the top surface with the recess and top and the buried chip components being arranged in a sealed cavity enclosed between protection layer and the substrate.

5. The electric device of claim 1,
comprising a mold applied over the protection layer.

6. The electric device of claim 1,
wherein the chip components are independently chosen from active or passive components, an IC, an acoustic wave component, a SAW device, a BAW device, a MEMS device and an RF filter device.

7. The electric device of claim 1,
wherein the protection layer comprises a lamination foil chosen from a plastic film or a coated plastic film.

8. The electric device of one of claim 1,
wherein the at least one top chip component is mounted to top contact pads arranged on the top surface near and along the edges of the recess
wherein the at least one buried chip component is mounted to bottom contact pads arranged on the bottom surface of the recess
wherein electrical interconnects of the top chip component to the top contact pads and of the buried chip component to the bottom contact pads are made by SMT interconnect, solder bumps, stud bumps, copper pillars or an electrically conductive adhesive.

9. The electric device of claim 1,
the height of the recess and the height of the second interconnects (IN_{T}) are chosen to leave a gap between top surface of buried chip component (BC) and the bottom surface of the top chip component (TC) mounted above.
